(19) United States
(12) Patent Application Publication
(10) Pub. No.: US 2011/0186856 A1
(43) Pub. Date: Aug. 4, 2011

(54) LIGHT EMITTING ELEMENT AND METHOD FOR MANUFACTURING THE SAME

(75) Inventors: SHIH-CHENG HUANG, Hsinchu (TW); PO-MIN TU, Hsinchu (TW); PENG-YI WU, Hsinchu (TW)

(73) Assignee: ADVANCED OPTOELECTRONIC TECHNOLOGY, INC., Hsinchu Hsien (TW)

(21) Appl. No.: 12/965,926

(22) Filed: Dec. 13, 2010

(30) Foreign Application Priority Data
Jan. 29, 2010 (TW) 99102579

(51) Int. Cl. H01L 33/30

(52) U.S. Cl. 257/76; 257/E33.025

(57) ABSTRACT

A method for manufacturing a light emitting element includes providing a substrate, forming a buffer layer on the substrate, forming a GaN layer on the buffer layer, forming a rough layer on the GaN layer at low temperature, and forming an epitaxial layer on the rough layer, wherein a refraction index of the epitaxial layer exceeds a refraction index of the rough layer. Thus, most light scatters at the rough layer, and then emits upwardly to a light emitting surface, enhancing light extraction efficiency thereof. An epitaxial process of the method is processed in situ in an MOCVD reactor.

### BACKGROUND

1. Technical Field

The disclosure relates to light emitting elements, and particularly to a light emitting element with a rough layer.

2. Description of the Related Art

Light emitting diodes' (LEDs) many advantages, such as high luminosity, low operational voltage, low power consumption, compatibility with integrated circuits, easy driving, long term reliability, and environmental friendliness have promoted their wide use as a lighting source. Now, light emitting elements are commonly applied in illumination apparatus.

Because the optical path of light from an active layer of common light emitting element is not perfect, light extraction efficiency and illuminating efficiency of common light emitting elements can be diminished.

Therefore, it is desirable to provide a light emitting element with a rough layer which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting element with a rough layer. Moreover, in the drawings, like reference numerals designate corresponding parts throughout the views.

FIG. 1 is a schematic view of a substrate in accordance with a first embodiment.

FIG. 2 is a schematic view of a buffer layer and an undoped GaN layer sequentially grown on the substrate of FIG. 1.

FIG. 3 is a schematic view of a rough layer grown on the undoped GaN layer of FIG. 2.

FIG. 4 is a top view of the rough layer of FIG. 3

FIG. 5 is a schematic view of a light emitting element in accordance with the first embodiment.

FIG. 6 is a schematic view of optical paths of light from an active layer of the light emitting element of FIG. 5.

FIG. 7 is a Scanning Electron Microscope image of an AlN layer grown at low temperature.

### DETAILED DESCRIPTION

Embodiments of a light emitting element with a rough layer as disclosed are described in detail here with reference to the drawings.

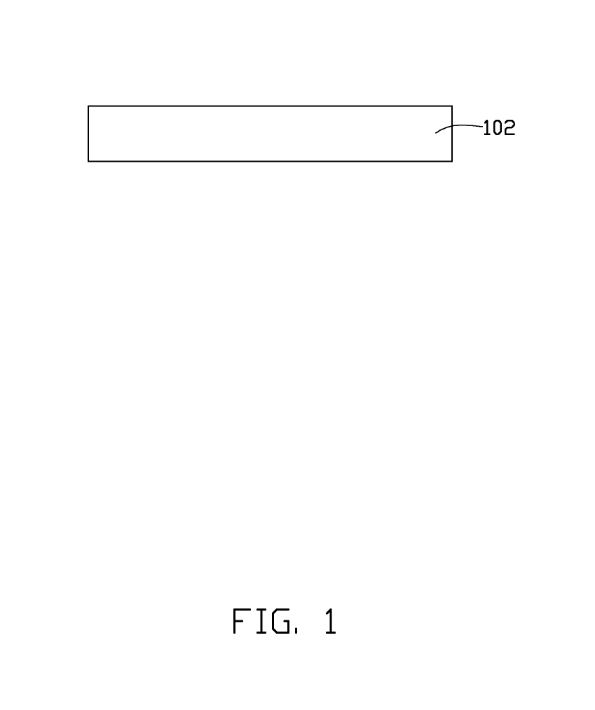

Referring to FIG. 1, a substrate 102, such as Al₂O₃, SiC, LiAlO₂, LiGaO₂, Si, GaN, ZaO, AlZnO, GaAs, GaP, GaSb, InP, InAs, of ZnSe is provided, although the substrate 102 is not limited thereto.

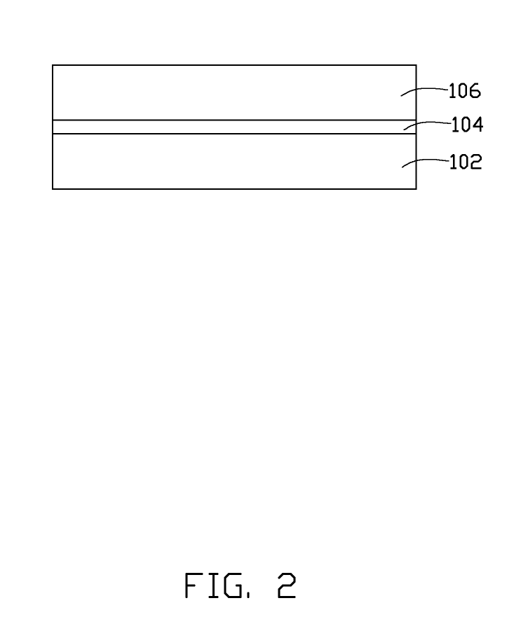

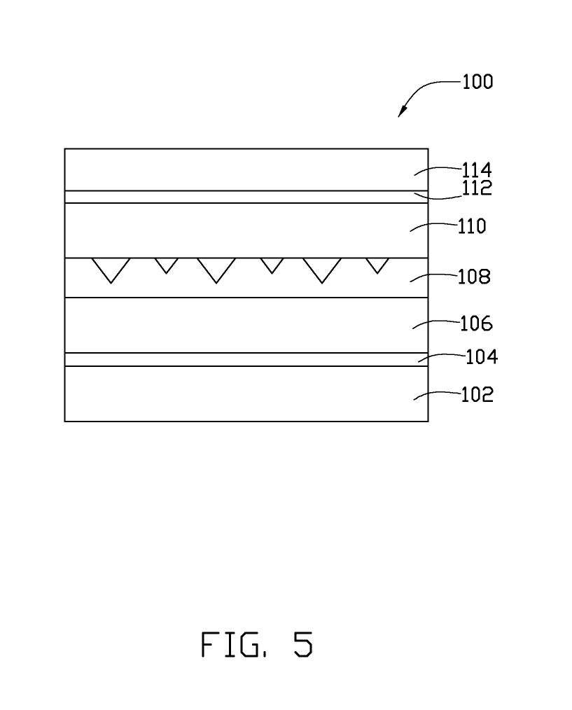

Referring to FIG. 2, a buffer layer 104 is formed on the substrate 102. It is well known that the lattice structure and the lattice constant of substrate 102 are important factors in selection of the substrate 101 When the difference of lattice constant between the substrate 102 and an epitaxial layer 116 (see FIG. 5) is excessive, the buffer layer 104 is required on the substrate 102 to obtain a good quality epitaxial layer 116. The buffer layer 104 is deposited at temperatures lower than epitaxial temperature by Chemical Vapor Deposition (CVD), for example, Metal Organic Chemical Vapor Deposition (MOCVD), or Molecular Beam Epitaxy (MBE).

The epitaxial temperature of the GaN is usually between 800° C. and 1400° C. The growing temperature of the buffer layer 104 is between 250° C. and 700° C. When utilizing MOCVD, the precusor of nitride can be NH₃ or N₂, and the precursor of gallium (Ga) can be trimethylgallium (TMGa) or triethylgallium (TEGa). The pressure of the reactor can be low or normal pressure. The reaction temperature is increased to between 1000° C. and 1400° C. to form an undoped GaN layer 106 on the buffer layer 104.

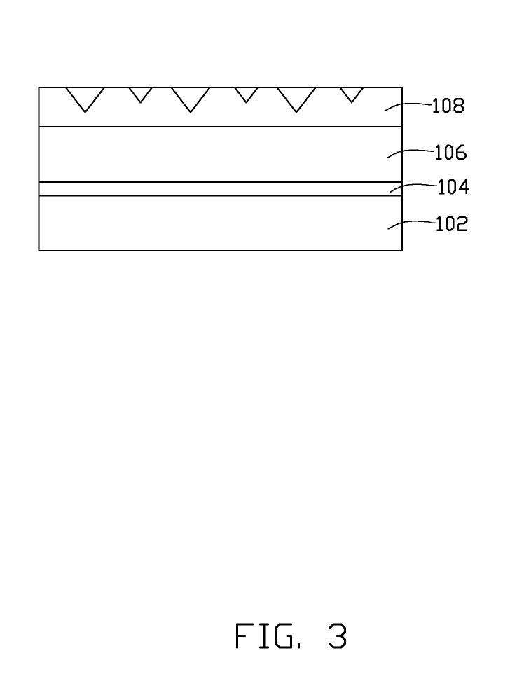

Referring to FIG. 3, a rough layer 108 formed on the undoped GaN layer 106 can be inorganic material, such as metal nitride. In this embodiment, the rough layer 108 is a single crystal AlN. The thickness of the rough layer 108 is between 0.5 μm and 2 μm. The thickness of the rough layer 108 is not limited to this embodiment. The rough layer 108 is deposited by MOCVD at 800° C. Trimethylaluminum (TMAl) is used as a precursor, with NH₃ gas to form the AlN layer 108 by MOCVD. A refractive index of an AlN layer, as the rough layer 108, is 2.1 in this embodiment.

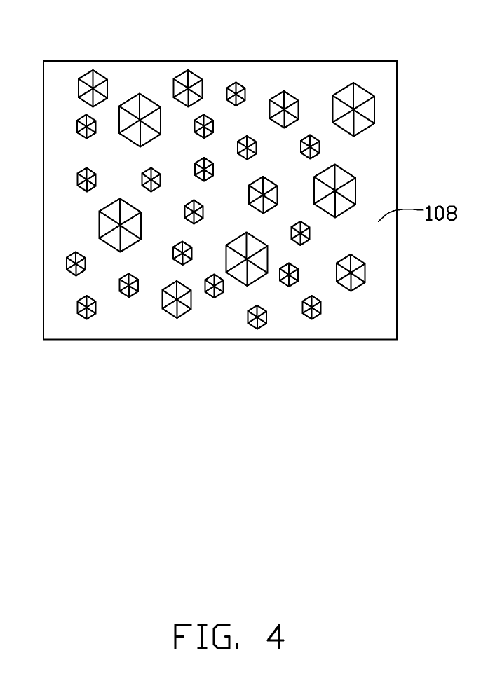

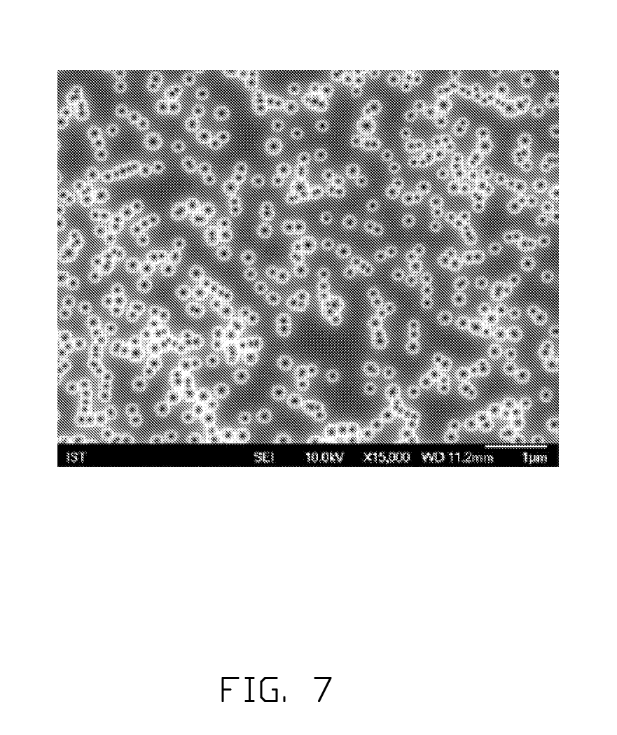

Referring to FIGS. 3 and 4, the lattice of the AlN layer as the rough layer 108 formed at 800° C. is disordered. Thus, the surface of the AlN rough layer 108 can scatter the light from an active layer and change the optical path of the light emitting element, enhancing light extraction efficiency. The rough layer 108 can be formed in the same reactor. FIG. 7 shows a Scanning Electron Microscope (SEM) image of surface of the AlN rough layer 108 grown at low temperature. The lattice of the AlN rough layer 108 grown at low temperature is disordered. Thus, the AlN rough layer 108 has a rough surface observed by the SEM picture.

Referring to FIG. 5, the epitaxial layer 116 is formed on the rough layer 108. The epitaxial layer 116 comprises a first semiconductor layer 110, an active layer 112, and a second semiconductor layer 114. A refractive index of the epitaxial layer 116 exceeds that of the rough layer 108. The first semiconductor layer 110 can be an n type semiconductor layer doped with group IV atoms. In this embodiment, the group IV atoms are silicon. The precursor of the Si is SiH₄ or Si₂H₆. The first semiconductor layer 110 sequentially consists of layers from a GaN layer doped with high concentration Si atoms to a GaN layer doped with low concentration Si atoms. The GaN layer doped with high concentration Si atoms provides Ohmic contact of the first semiconductor layer 110.

An active layer 112 is formed on the n-type first semiconductor layer 110. The active layer 112 can be single hetero-structure, double hetero-structure, single quantum well, or multiple quantum wells. The commonly used active layer is multiple quantum wells. The quantum well can be InGaN, and a barrier layer can be AlGaN. Furthermore, a Quanternary AlₓIn_{y}Ga_{1-x-y}N can also be the quantum well and the barrier layer. By adjusting the molar ratio of the Al and In atoms, the energy level of the AlₓIn_{y}Ga_{1-x-y}N can be a high energy level of the barrier layer and low energy level of the quantum well. The active layer 112 can respectively be doped with n type or p type dopant. The active layer 112 can also be doped with n type and p type dopant simultaneously. The active layer 112 also can be undoped. Moreover, the quantum well can be doped with the barrier layer undoped. By other methods, the quantum well can be undoped with the barrier layer doped. The quantum well and the barrier layer can be both undoped or doped.

A p-type semiconductor barrier layer (not shown) is formed on the active layer 112. The p-type semiconductor barrier layer includes a first III-VI semiconductor layer and a second III-VI semiconductor layer. The two layers provide different energy gaps and are deposited successively on the active layer 112. The barrier layer, having a higher energy barrier is formed by deposition and avoids electron overflow to the active layer 112. The first III-VI semiconductor layer can be AlₓIn_{y}Ga_{1-x-y}N and the second III-VI semiconductor layer can be AlᵤInᵥGa₁₋ᵤ₋ᵥN, wherein the 0<x≦1, 0≦y<1, x+y≦1, 0≦u<1, 0≦v 1, and u+v 1. When x=u, y≠v. Moreover, the—semiconductor layer can also be GaN, AlN, InN, AlGaN,

InGaN, or AlInN.

Finally, the p-type semiconductor layer 114 doped with atoms is formed on the p-type semiconductor barrier layer. The precursor of magnesium (Mg) is CP₂Mg in MOCVD. The p-type semiconductor 114 is formed sequentially from the GaN layer doped with low concentration magnesium (Mg) to the GaN layer doped with high concentration magnesium (Mg). The GaN layer doped with high concentration magnesium (Mg) provides Ohmic Contact.

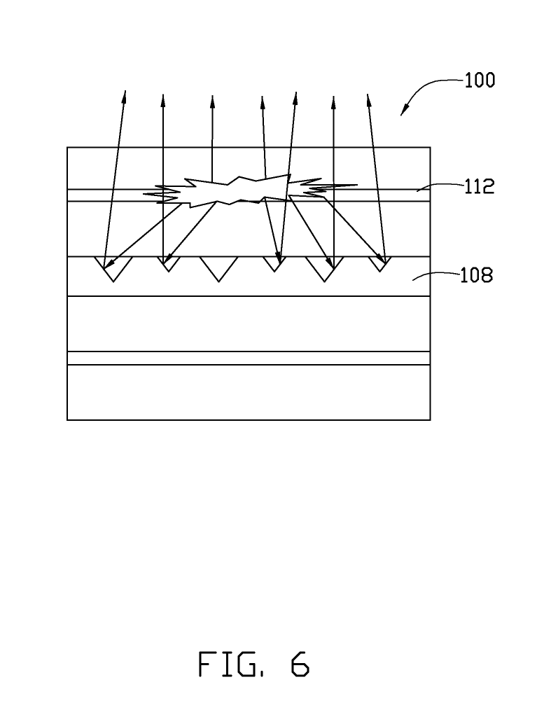

Referring to FIG. 6, light from the active layer 112 is emitted upwardly and downwardly. Light from the active layer 112 emitting downwardly produces scattering and diffused reflection by the rough surface of the rough layer 108. That changes the optical path of light from the active layer 112 and increases the light extraction efficiency.

The material of the rough layer 108 must consider lattice match of the rough layer 108 and the epitaxial layer 116. It is well known that the lattice characteristic of the rough layer 108 affects directly the quality of the epitaxial layer 116.

When the rough layer 108 and the epitaxial layer 116 have lattice mismatch, dislocation density of the epitaxial layer 116 increases and causes the device to fail.

Moreover, the refraction index of the rough layer 108 and the epitaxial layer 116 must be different. The larger the difference of the refraction index is, the more scattering occurs. In this embodiment, the refraction index of the rough layer 108 must be smaller than that of the epitaxial layer 116. Thus, most light scatters at the rough layer 108, and then emits upwardly to a light emitting surface, enhancing light extraction efficiency thereof. For example, the refractive index of the epitaxial layer 116 of GaN can be 2.5, and that of the rough layer of the AlN 2.1. Moreover, the rough layer 108 can be inorganic material.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing a light emitting element, including steps:
providing a substrate;
forming a buffer layer on the substrate;
forming a rough layer on the buffer layer;
forming an epitaxial layer on the rough layer; wherein all above steps are completed in a reactor.

2. The method for manufacturing the light emitting element of claim 1 further comprising forming a GaN layer between the buffer layer and the rough layer.

3. The method for manufacturing the light emitting element of claim 1, wherein the rough layer is AlN.

4. The method for manufacturing the light emitting element of claim 1, wherein the refractive index of the epitaxial layer exceeds that of the rough layer.

5. The method for manufacturing the light emitting element of claim 1, wherein a growing temperature of the rough layer is lower than that of the epitaxial layer.

6. A light emitting element, comprising:
a substrate;
a buffer layer on the substrate;
a rough layer on the buffer layer; and
an epitaxial layer on the rough layer.

7. The light emitting element of claim 6 further including a GaN layer between the buffer layer and the rough layer.

8. The light emitting element of claim 6, wherein the rough layer is AlN.

9. The light emitting element of claim 6, wherein a refractive index of the epitaxial layer exceeds that of the rough layer.

10. The light emitting element of claim 6, wherein a thickness of the rough layer is 0.2-0.8 μm.
